(19) United States
(12) Patent Application Publication
(10) Pub. No.: US 2025/0374837 A1
(43) Pub. Date: Dec. 4, 2025

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Yen-Liang Lin, Taichung City (TW); Chin I Wang, Tainan City (TW)

(73) Assignee: Taiwan Semiconductor Manufacturing Company, Ltd., Hsinchu (TW)

(21) Appl. No.: 18/675,159

(22) Filed: May 28, 2024

(51) Int. Cl. H10N 70/00; H10B 63/00

(52) U.S. Cl. CPC H10N 70/861; H10B 63/80; H10N 70/021; H10N 70/068; H10N 70/841; H10N 70/883

(57) ABSTRACT

A semiconductor structure includes a memory device including a first electrode layer, a second electrode layer disposed over the first electrode layer, and a data storage structure interposed between the first electrode layer and the second electrode layer. The data storage structure includes a first layer and a second layer. A thermal conductivity of the first layer is different from that of the second layer.

### BACKGROUND

Many modern electronic devices contain electronic memory configured to store data. Electronic memory may be volatile memory or non-volatile memory. Volatile memory stores data while it is powered, whereas non-volatile memory is able to store data even if power is removed. Resistive random access memory (RRAM) is one promising candidate for next generation non-volatile memory technology due to its simple structure and its compatibility with complementary metal-oxide-semiconductor (CMOS) logic fabrication processes. Although existing semiconductor structures with memory devices have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic cross-sectional view of a semiconductor structure with a memory device, in accordance with some embodiments.

FIGS. 2-8 illustrate schematic cross-sectional views of intermediate steps during a process for forming a memory device, in accordance with some embodiments.

FIG. 9 illustrates a schematic cross-sectional view of a variation of the structure shown in FIG. 8, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In integrated circuit (IC) devices, resistive random access memory (RRAM) is an emerging technology for next generation non-volatile memory devices. RRAM is a memory structure including an array of RRAM cells and is configured to store data by switching between different resistances that correspond to different data states, thereby enabling the respective memory cell to store one or more bit of data. The RRAM device may have an upper electrode layer and a lower electrode layer separated from the upper electrode layer by a data storage layer (or called “a resistance switching layer”), where the resistance of the data storage layer may be adjusted to represent logic “0” or logic “1”. The data storage layer may include one or more dielectric material(s) that is/are able to alter its internal resistance in response to an applied bias. Different dielectric materials in the data storage layer may provide the RRAM device with different characteristics. It has been observed that in some cases, after baking tests on the RRAM device, a sharp local temperature peak (also called “a hot spot”) occurs at a region of the data storage layer proximal to the lower electrode layer. A challenge with the data storage layer may pertain to heat dissipation at operating/baking temperatures.

Moreover, it is appreciated that a read window is a difference between currents read out from the RRAM device between a “1” and a “0”. During operation of the RRAM device, a sufficiently large read window is desirable to be maintained, since a larger read window makes it easier to differentiate between different data states during operation of the RRAM. Furthermore, the RRAM device operates under the principle that a dielectric data storage layer may be made conductive through conductive path/filaments formed after the application of a sufficiently high voltage (also called “forming voltage”). A challenge with the RRAM device used in, e.g., automotive electronics, computing, and communication applications, pertains to achieve lower forming voltage, larger read window, and better thermal stability/conductivity.

Embodiments discussed herein are to provide a semiconductor structure having a memory device and methods for forming the same. For example, the memory device includes an upper electrode layer and a lower electrode layer separated from the upper electrode by a data storage structure. The data storage structure may include different material layers. The bottom portion of the data storage structure proximal to the lower electrode layer may be configured to provide improved thermal stability and improved thermal conductivity for the memory device.

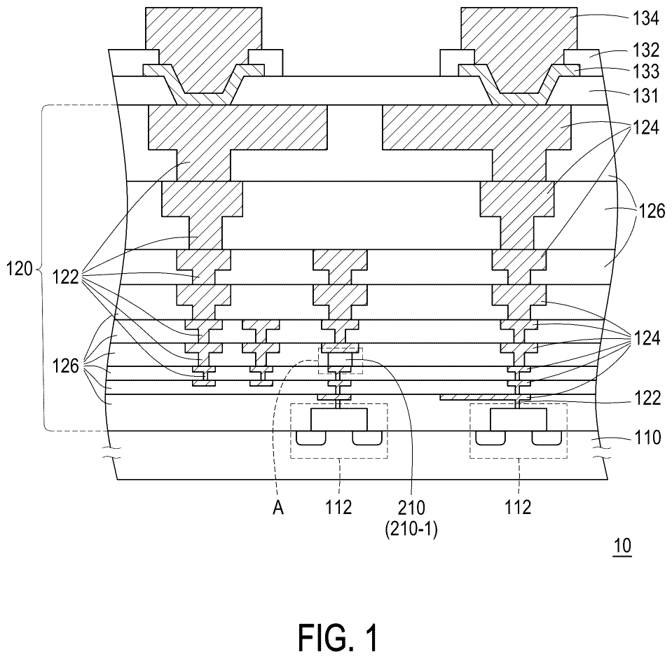

FIG. 1 illustrates a schematic cross-sectional view of a semiconductor structure 10 with a memory device 210, in accordance with some embodiments. Referring to FIG. 1, the semiconductor structure 10 may include a semiconductor substrate 110, an interconnect structure 120 disposed over the semiconductor substrate 110, a passivation layer 131 disposed over the interconnect structure 120, a post-passivation layer 132 disposed over the passivation layer 131, contact pads 133 disposed on and passing through the passivation layer 131 to be electrically connected to the interconnect structure 120, and conductive terminals 134 landing on the contact pads 133. The semiconductor substrate 110 may be a bulk semiconductor substrate, a semiconductor-on-insulator (SOI) substrate, a multi-layered substrate, a gradient substrate, or the like. In some embodiments, the material of the semiconductor substrate 110 includes silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

Devices, such as active devices (e.g., transistors, diodes, etc.), capacitors, resistors, or the like, may be formed in/on the front side of the semiconductor substrate 110. The devices are represented by transistors 112 in the illustrated embodiment. For example, the semiconductor substrate 110 includes various doped regions doped with p-type dopants or n-type dopants, depending on the circuit requirements. In some embodiments, the doped regions serve as source/drain regions of the respective transistor 112. Depending on the types of the dopants in the doped regions, the respective transistor 112 may be referred to as n-type transistor or p-type transistor. In some embodiments, the respective transistor 112 includes a metal gate located above the semiconductor substrate 110 and embedded in the interconnect structure 120 and a channel under the metal gate and located between the source/drain regions, where the channel serves as a path for electron to travel when the respective transistor 112 is turned on. In some embodiments, the transistors 112 are formed using suitable Front-end-of-line (FEOL) process and may be referred to as the FEOL device. It should be understood that the number of the transistors 112 may be formed depending on the application of the semiconductor structure 10 and construes no limitation in the disclosure.

With continued reference to FIG. 1, the interconnect structure 120 may include conductive vias 122, conductive patterns 124, and dielectric layers 126 covering the conductive vias 122 and the conductive patterns 124. The conductive patterns 124 located at different level heights may be physically and electrically connected to one another through the conductive vias 122. In some embodiments, the bottommost conductive vias 122 are connected to the metal gate of the transistor 112 which is embedded in the bottommost dielectric layer 126. It should be noted that in alternative cross-sectional views, other bottommost conductive vias 122 are also connected to source/drain regions of the respective transistor 112. The material(s) of the conductive patterns 124 and the conductive vias 122 may include aluminum, titanium, copper, nickel, tungsten, alloys, a combination thereof, etc. In some embodiments, the material of the dielectric layers 126 includes polyimide, benzocyclobutene (BCB), polybenzooxazole (PBO), or any other suitable dielectric material. Alternatively, the dielectric layers 126 may be formed of oxides or nitrides, such as silicon oxide, silicon nitride, or the like. The dielectric layers 126 may be referred to as inter-metal dielectric (IMD) layers. It should be noted that the number of the dielectric layers 126, the number of the conductive patterns 124, and the number of the conductive vias 122 illustrated in FIG. 1 are merely for illustrative purposes and construe no limitation in the disclosure. It should be noted that fewer or more layers of the dielectric layers 126, the conductive patterns 124, and/or the conductive vias 122 may be formed depending on the circuit design.

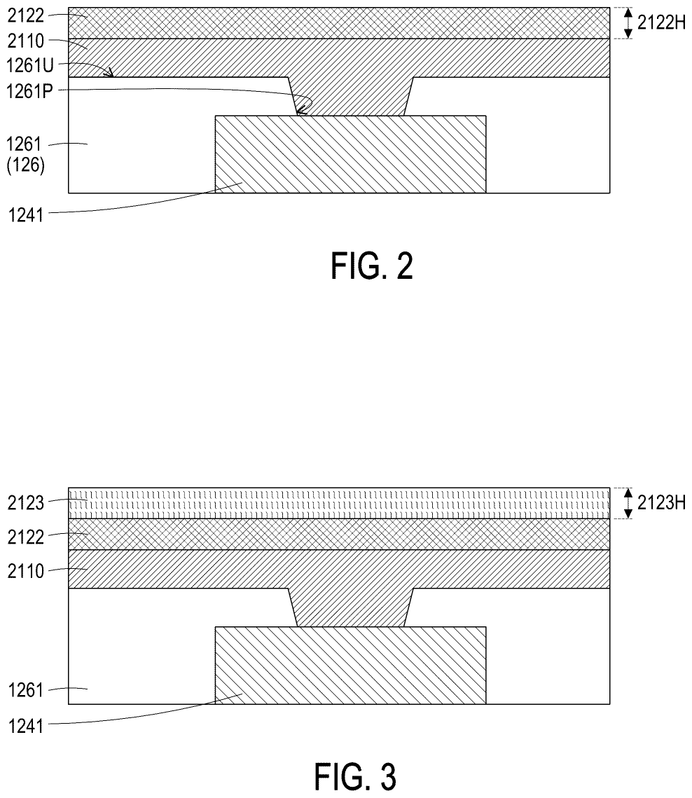

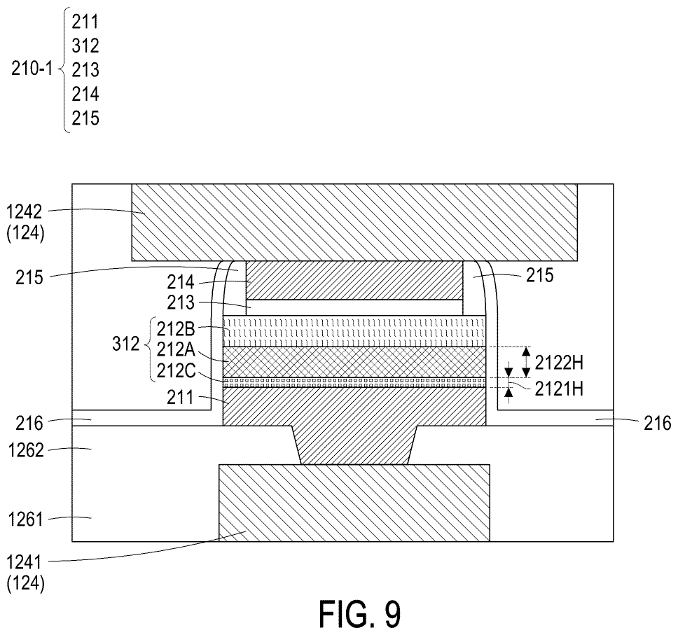

With continued reference to FIG. 1, the memory device 210 may be embedded in the interconnection structure 120. The location of the memory device 210 shown in FIG. 1 is merely an example, and the memory device 210 may be embedded in any one of the dielectric layers 126. In some embodiments, the memory device 210 is formed during back-end-of-line (BEOL) process. For example, the memory device 210 is electrically coupled to the logic device (e.g., the transistor 112) through the conductive patterns 124 and/or the conductive vias 122, and the logic device may support operation of the memory device 210. Although a single memory device 210 is shown in FIG. 1 for the sake of simplicity; however, it should be understood that a plurality of memory devices 210 may be formed depending on the application of the semiconductor structure 10. The manufacturing method and the detailed structure of the memory device 210 will be described below in conjunction with FIGS. 2-9. In alternative embodiments, the memory device 210 is replaced with a memory device 210-1 described in FIG. 9.

With continued reference to FIG. 1, the passivation layer 131, the contact pads 133, the post-passivation layer 132, and the conductive terminals 134 are sequentially formed on the interconnect structure 120. In some embodiments, the passivation layer 131 is disposed on the topmost dielectric layer 126 and the topmost conductive patterns 124. In some embodiments, the passivation layer 131 has a plurality of openings exposing at least a portion of the topmost conductive patterns 124. In some embodiments, the passivation layer 131 is a silicon oxide layer, a silicon nitride layer, a silicon oxy-nitride layer, or a dielectric layer formed by other suitable dielectric materials. In some embodiments, the contact pads 133 are formed over the passivation layer 131 and extend into the openings of the passivation layer 131 to be in physical and electrical contact with the topmost conductive patterns 124. In some embodiments, the contact pads 133 include aluminum pads, copper pads, titanium pads, nickel pads, tungsten pads, and/or other suitable metal pads. It should be noted that the number and the shape of the contact pads 133 illustrated in FIG. 1 are merely for illustrative purposes and construe no limitation in the disclosure.

In some embodiments, the post-passivation layer 132 is optionally formed over the passivation layer 131 and the contact pads 133. The post-passivation layer 132 may have openings exposing at least a portion of the conductive pads 133. The post-passivation layer 132 may be a polyimide layer, a PBO layer, or a dielectric layer formed by other suitable polymers. In some embodiments, the conductive terminals 134 are formed over the post-passivation layer 132 and extend into the openings of the post-passivation layer 132 to be in physical and electrical contact with the corresponding conductive pad 133. In some embodiments, the conductive terminals 134 are conductive pillars, conductive posts, conductive balls, conductive bumps, or the like. The conductive terminals 134 may be made of aluminum, titanium, copper, nickel, tungsten, tin, and/or alloys thereof. In some embodiments, the conductive terminals 134 are used to establish electrical connection with other components (not shown) subsequently formed or provided.

It should be noted that FIG. 1 is provided for illustrative purposes only, and the semiconductor structure 10 may utilize fewer or additional elements according to some embodiments. One or more packaging/semiconductor process may be performed on the semiconductor structure 10 depending on product requirements. The advanced packaging technologies enable production of semiconductor structure 10 with enhanced functionalities. The embodiments described herein are not intended to be limited to the embodiments described, and the embodiments may be implemented in any suitable methods and structures (e.g., integrated fanout packages, package-on-package, chip-on-wafer-on-substrate packages, system-on-integrated-circuit structure, etc.). All such embodiments are fully intended to be included within the scope of the embodiments.

FIGS. 2-8 illustrate schematic cross-sectional views of intermediate steps during a process for forming the memory device 210, in accordance with some embodiments. Like reference numerals denote like features with similar structures and compositions.

Referring to FIG. 2 and with reference to FIG. 1, a first dielectric layer 1261 of the dielectric layers 126 may cover a first conductive pattern 1241 of the conductive patterns 124. In some embodiments, the first dielectric layer 1261 has an opening 1261P exposing at least a portion of the first conductive pattern 1241. A lower electrode material layer 2110 may be formed on an upper surface 1261U of the first dielectric layer 1261 and may extend into the opening 1261P to be in contact with the first conductive pattern 1241. The lower electrode material layer 2110 may be formed by chemical vapor deposition (CVD), physical vapor deposition (PVD), atomic layer deposition (ALD), sputtering, plating, or other suitable process. The lower electrode material layer 2110 may be made of ruthenium, molybdenum, platinum, aluminum, copper, titanium, gold, titanium nitride, tantalum, tantalum nitride, tungsten, tungsten nitride, alloys thereof, a combination thereof, and/or the like.

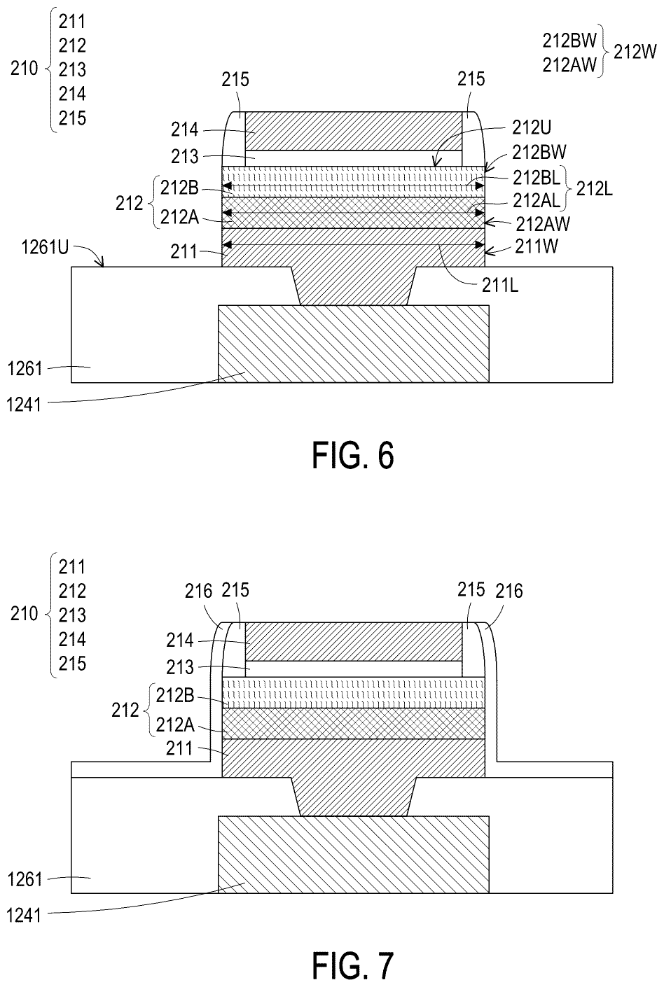

With continued reference to FIG. 2, a first material layer 2122 of a data storage structure (‘212’ labeled in FIG. 6) is formed on the lower electrode material layer 2110 by PVD or other suitable deposition process (e.g., CVD, ALD, etc.). The thickness 2122H of the first material layer 2122 may be in a range of about 5 angstroms and 50 angstroms, such as about 10 angstroms to 30 angstroms. Other thickness value may be used, depending on process and product requirements. The first material layer 2122 may be or include one or more layers of metal oxynitride, metal oxide, metal nitride, the like, a combination thereof, etc. In some embodiments, the first material layer 2122 is made of N-containing layer or N-containing oxide. For example, the first material layer 2122 is made of a metal oxynitride layer, such as an aluminum oxynitride (AlOₓN_{y}) layer. The nitrogen to oxygen (N/O) ratio of the aluminum oxynitride layer (e.g., 2122) may be controlled by adjusting process condition(s), such as tuning the plasma power or process temperature. In some embodiments, the N/O ratio of the first material layer 2122 is equal to or greater than 0.25. For example, the N/O ratio of the first material layer 2122 is in a range of about 0.25 and about 3, inclusive.

In some embodiments, the memory device employs oxygen vacancies to form conductive filaments. The first material layer 2122 may have a relative density of 90% or less. For example, during the formation of the first material layer 2122, a power of a DC power source may be lowered to achieve a lower film relative density. Other approaches (e.g., adjusting various process conditions) may be used. In some embodiments, after the deposition of the first material layer 2122, a plasma treatment is performed on the first material layer 2122. For example, more oxygen may be supplied to the first material layer 2122 by changing the conditions of the plasma treatment. During the plasma treatment, the ion bombardment is applied to the first material layer 2122, thereby increasing oxygen vacancies in the first material layer 2122. In alternative embodiments, the plasma treatment is omitted. In some alternative embodiments, the first material layer 2122 may be or include aluminum nitride (AlN), aluminum oxide (AlₓO_{y}), hafnium nitride (HfN), hafnium oxide (HfOₓ), hafnium oxynitride (HfOₓN_{y}), the like, combinations thereof, suitable high-k dielectric material(s), or other suitable dielectrics. For example, compared to the subsequently-formed second material layer (‘2123’ labeled in FIG. 3), the first material layer 2122 is made of the material(s) having a higher melting point and/or a better thermal conductivity. In some embodiments, the first material layer 2122 has a melting point greater than (or substantially equal to) about 2000° C. In some embodiments, the first material layer 2122 has a thermal conductivity greater than (or substantially equal to) about 1.1 watts per meter kelvin (W/mK).

Referring to FIG. 3 and with reference to FIG. 2, a second material layer 2123 of the data storage structure (‘212’ labeled in FIG. 6) is formed on the first material layer 2122 by any suitable deposition process. The thickness 2123H of the second material layer 2123 may be in a range of about 5 angstroms and 30 angstroms. Other thickness value may be used, depending on process and product requirements. The second material layer 2123 is or includes one or more layer(s) of hafnium-based dielectric, tantalum-based dielectric, zirconium-based dielectric, some other suitable high-k dielectric(s), some other suitable dielectric(s), combinations thereof, and/or the like. The second material layer 2123 is different from the first material layer 2122. In some embodiments, the second material layer 2123 has a relative density of 90% or higher. The relative density of the second material layer 2123 is higher than that of the first material layer 2122. The second material layer 2123 may have a greater amount of oxygen vacancies than the first material layer 2122. In some embodiments, the first material layer 2122 has the melting point higher than the melting point of the second material layer 2123. In some embodiments, the first material layer 2122 has the melting point of at least about 1.2 times the melting point of the second material layer 2123. In some embodiments, the thermal conductivity of the first material layer 2122 is at least about 30 times greater than the thermal conductivity of the second material layer 2123.

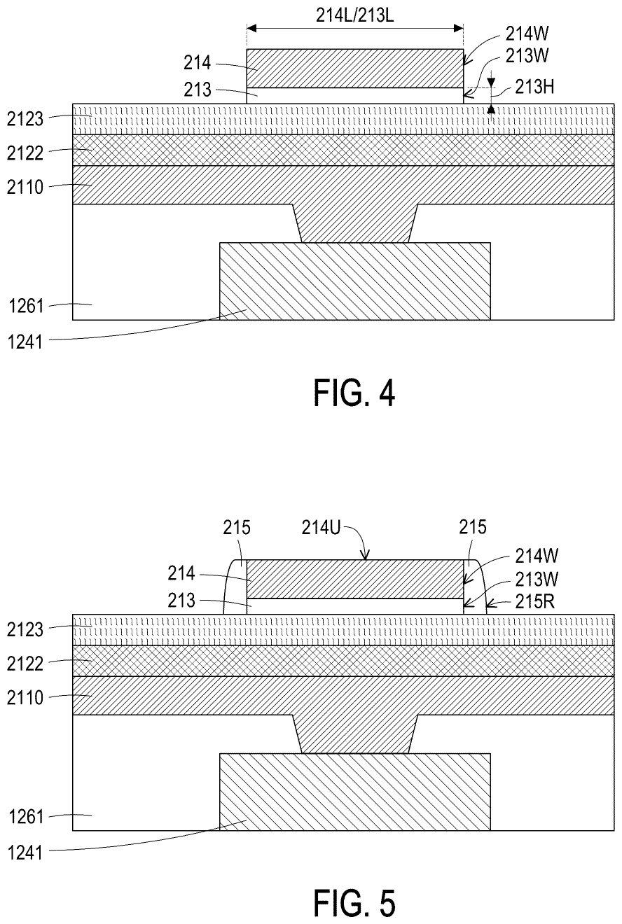

Referring to FIG. 4 and with reference to FIG. 3, a capping layer 213 may be formed on the second material layer 2123 of the data storage structure (‘212’ labeled in FIG. 6). An upper electrode layer 214 may be disposed on the capping layer 213. For example, a layer of capping material and a layer of upper electrode material are sequentially formed on the second material layer 2123, and a mask layer (not shown) may then be formed on the layer of upper electrode material to protect the underlying material layers from a subsequent process. One or more removing process (e.g., etching or the like) may be performed to remove the exposed portions of the capping material and upper electrode material layers which are not covered by the mask layer. The remaining portions of the capping material and upper electrode material layers may form the capping layer 213 and the upper electrode layer 214, respectively. Subsequently, the mask layer may be removed from the upper electrode layer 214. However, other suitable forming processes may be performed to form the capping layer 213 and the upper electrode layer 214.

With continued reference to FIG. 4, the capping layer 213 may be made of tantalum nitride, titanium nitride, suitable metal (e.g., platinum, aluminum copper, gold, titanium, tantalum, tungsten, copper, etc.), and/or the like. The capping layer 213 may have a thickness 213H less than each of the thicknesses (‘2122H’ and ‘2123H’; labeled in FIGS. 2-3) (or an overall thickness) of the first and second material layers (2122 and 2123). The upper electrode layer 214 may be made of titanium, tantalum, suitable metal (e.g., platinum, aluminum, copper, gold, tungsten, etc.), a combination thereof, and/or the like. In some embodiments, the capping layer 213 is made of a different material than the upper electrode layer 214. In some embodiments, the upper electrode layer 214 and the lower electrode material layer 2110 are made of different materials from one another. In some embodiments, the lateral dimension 214L of the upper electrode layer 214 is substantially equal to the lateral dimension 213L of the capping layer 213. The sidewall 214W of the upper electrode layer 214 may be substantially aligned (or coplanar) with the sidewall 213W of the capping layer 213, within process variations.

Referring to FIG. 5 and with reference to FIG. 4, sidewall spacers 215 may be formed on the second material layer 2123 and extend along the sidewalls (213W and 214W) of the capping layer 213 and the upper electrode layer 214. The sidewall spacers 215 may be made of any suitable dielectric material, such as silicon nitride, silicon carbide, an oxide, and/or the like. For example, a layer of sidewall spacer material is deposited on the upper surface of the second material layer 2123 and buries the stack of the capping layer 213 and the upper electrode layer 214, and then a patterning process (e.g., etching or the like) may be performed on the layer of sidewall spacer material to remove excess portions of the sidewall spacer material so as to form the sidewall spacers 215. The upper surface 214U of the upper electrode layer 214 may be accessibly exposed by the sidewall spacers 215. The outer surface 215R of the respective sidewall spacer 215 distal to the sidewalls (214W and 213W) may be curved or rounded according to some embodiments. For example, the lateral thickness on the sidewall 214 of the upper electrode layer 214 increases from the point proximal to the upper surface 214U of the upper electrode layer 214 to the point distal to the upper surface 214U. The sidewall spacers 215 may have a cross-sectional profile different than shown.

Referring to FIG. 6 and with reference to FIG. 5, the second material layer 2123, the first material layer 2122, and the lower electrode material layer 2110 may be partially removed to form the data storage structure 212 and the lower electrode layer 211 underlying the data storage structure 212, where the data storage structure 212 includes the first layer 212A and the second layer 212B overlying the first layer 212A. For example, a mask layer (not shown) is formed on the upper surfaces of the upper electrode layer 214 and the sidewall spacers 215, and then one or more removing process (e.g., etching or the like) may be performed on the second material layer 2123, the first material layer 2122, and the lower electrode material layer 2110 to remove the exposed portions which are not covered by the sidewall spacers 215 and the stack of the upper electrode layer 214 and the capping layer 213. The remaining portions of the second material layer 2123, the first material layer 2122, and the lower electrode material layer 2110 may form the second layer 212B, the first layer 212A, and the lower electrode layer 211, respectively. The upper surface 1261U of the first dielectric layer 1261 may be partially exposed by the stack of the second layer 212B, the first layer 212A, the lower electrode layer 211, and the overlying structures.

With continued reference to FIG. 6, the sidewall spacers 215 may be formed on the peripheral region of the upper surface 212U of the data storage structure 212, and the stack of the upper electrode layer 214 and the capping layer 213 may be formed on the central region of the upper surface 212U which is connected to and surrounded by the peripheral region. In some embodiments, the lateral dimension 212L of the data storage structure 212 is substantially equal to the lateral dimension 211L of the lower electrode layer 211. The lateral dimension 211L of the lower electrode layer 211 and/or the lateral dimension 212L of the data storage structure 212 may be greater than the lateral dimension (‘214L’ labeled in FIG. 4) of the upper electrode layer 214. The lateral dimension 212BL of the second layer 212B may be substantially equal to the lateral dimension 212AL of the first layer 212A. In some embodiments, the sidewall 212W of the data storage structure 212 is substantially aligned (or coplanar) with the sidewall 211W of the lower electrode layer 211, within process variations. The sidewall (‘214W’ labeled in FIG. 5) of the upper electrode layer 214 may be laterally displaced from the sidewall 211W of the lower electrode layer 211 and/or the sidewall 212W of the data storage structure 212. The sidewall 212BW of the second layer 212B may be substantially aligned (or coplanar) with the sidewall 212AW of the first layer 212A, within process variations.

Still referring to FIG. 6, the structure including the lower electrode layer 211, the data storage structure 212 stacked on the lower electrode layer 211, the capping layer 213 overlying the data storage structure 212, the upper electrode layer 214 overlying the capping layer 213, and the sidewall spacers 215 extending along the capping layer 213 and the upper electrode layer 214 may be collectively viewed as the memory device 210. The data storage structure 212 of the memory device 210 may include the first layer 212A overlying the lower electrode layer 211 and the second layer 212B vertically interposed between the first layer 212A and the capping layer 213. During operation of the memory device 210, the data storage structure 212 (also called “a resistive switching structure”) may have a variable resistance that represents a unit of data. The capping layer 213 overlying the data storage structure 212 may be configured to transfer oxygen ions corresponding to oxygen vacancies to and from conductive filaments in the data storage structure 212 to change the resistance of the data storage structure 212. The conductive filaments may be defined by defects in the data storage element, such as oxygen vacancies. It is appreciated that whether oxygen ions are stripped from the conductive filaments within the data storage structure 212 or stuffed into the data storage structure 212 depends on what bias is applied across the upper and lower electrode layers (214 and 211).

In some embodiments, an initialization operation is performed by applying a forming voltage across the upper electrode layer 214 and the lower electrode layer 211 to initially form the conductive filaments (not individually shown). For example, the forming voltage is applied to break the bonding between metal and oxygen, thereby forming oxygen vacancies, i.e. conductive filaments in the data storage structure 212. The localized vacancies tend to align to form the conductive filaments which may vertically extend through the data storage structure 212. In some embodiments, a first operation (e.g., a reset operation) is performed by applying a first voltage across the upper electrode layer 214 and the lower electrode layer 211 to switch the data storage structure 212 from a first resistance state (e.g., a lower resistance state) to a second resistance state (e.g., a high resistance state). For example, the ions move back from the ion reservoir region in the capping layer 213 to the data storage structure 212, thereby filling vacancies in the data storage structure 212 and breaking the conductive filaments to increase resistivity. In some embodiments, a second operation (e.g., a set operation) is performed by applying a second voltage across the upper electrode layer 214 and the lower electrode layer 211 to switch the data storage structure 212 from the second resistance state to the first resistance state. For example, the ions in the data storage structure 212 move to the ion reservoir region in the capping layer 213, thereby leaving vacancies and re-forming conductive filaments to lower resistivity.

With continued reference to FIG. 6, the second layer 212B of the data storage structure 212 may provide the greater amount of oxygen vacancies than the first layer 212A. For example, the first layer 212A proximity to the lower electrode layer 211 has a small amount of oxygen vacancies, and the second layer 212B proximity to the capping layer 213 has a larger amount of oxygen vacancies. The data storage structure 212 may have densities of oxygen vacancies and relative densities that change as a distance from the lower electrode layer 211 changes. For example, the first layer 212A has a first density of oxygen vacancies, and the second layer 212B has a second density of oxygen vacancies greater than the first density of oxygen vacancies. The second layer 212B may have the relative density greater than the relative density of the first layer 212A. By providing the greater amount of oxygen vacancies in the data storage structure 212, the memory device 210 with good performance voltage and yield may be achieved. For example, the forming voltage of the memory device 210 including the data storage structure 212 has been reduced as compared to the conventional data storage layer of the comparative example. For example, the forming voltage of the memory device 210 is about 2.4 volts or less.

In some embodiments, the first layer 212A includes the thermal conductivity higher than the thermal conductivity of the second layer 212B. In this way, the heat dissipation of the data storage structure 212, especially for the bottom of the data storage structure 212 proximity to the lower electrode layer 211, may be improved. In some embodiments, the first layer 212A has the melting point higher than the melting point of the second layer 212B. The high melting point material(s) may be used to provide stronger bonding to avoid breakdown and improve the thermal stability of the data storage structure 212. It is found that in some comparative cases, heat accumulates in the bottom portion of the data storage structure proximity to the lower electrode layer because of the poor thermal conductivity of the data storage structure. In detail, because the thermal conductivity of the bottom of the data storage structure in the comparative cases is less than approximately 1 W/mK, heat cannot be efficiently dissipated and may accumulate close to the interface between the lower electrode layer and the data storage structure. In addition, since the melting point of the bottom of the data storage structure is relatively low (e.g., about 1800 C), metal-oxide bonds are easily broken due to the heat accumulation. As mentioned above, the thermal conductivity of the first layer 212A of the data storage structure 212 is greater than approximately 1.1 W/mK; therefore, heat generated during the operation can be easily dissipated from the interface between the data storage structure 212 and the lower electrode layer 211, and thus heat accumulation at the interface may be reduced. The improved thermal stability of the first layer 212A of the data storage structure 212 may help improve the read window of the memory device 210 after cycling.

Referring to FIG. 7 and with reference to FIG. 6, dielectric liners 216 may be formed on the upper surface 1261U of the first dielectric layer 1261 and extend along the sidewalls (211W and 212W) of the lower electrode layer 212 and the data storage structure 212 and the outer surfaces 215R of the sidewall spacers 215. For example, a layer of dielectric material is conformally deposited over the structure shown in FIG. 6 to follow these upper surface/sidewalls/outer surfaces and may extend across the upper surface (‘214U’ labeled in FIG. 5) of the upper electrode layer 214, and then one or more removing process (e.g., etching or the like) may be performed to remove the portion of the dielectric material overlying the upper surface 214U of the upper electrode layer 214 so as to form the dielectric liners 216 shown in FIG. 7. The upper surface 214U of the upper electrode layer 214 may be accessibly exposed by the dielectric liners 216. The dielectric liners 216 may be formed silicon nitride, silicon carbide, or a combination of one or more of the foregoing. The dielectric liners 216 may act as a protective layer to protect the structure from the subsequent processing steps. In alternative embodiments, the dielectric liners 216 are omitted.

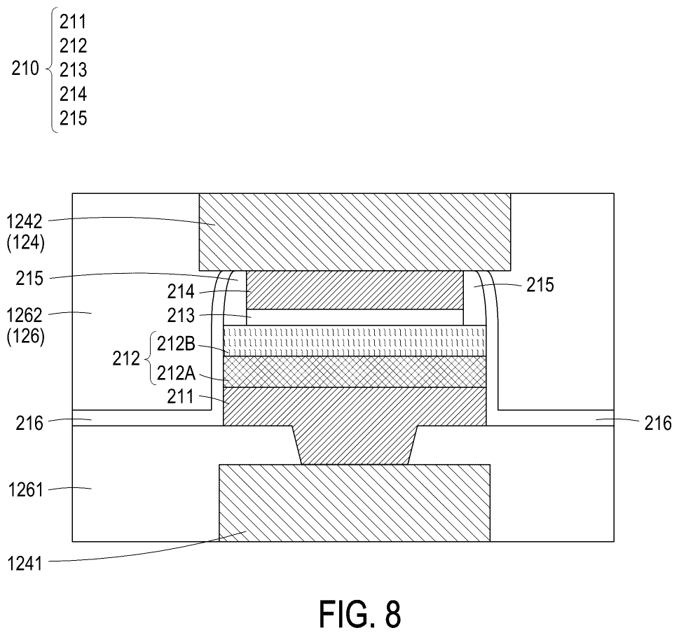

Referring to FIG. 8 and with reference to FIG. 7 and FIG. 1, a second dielectric layer 1262 of the dielectric layers 126 may be formed on the dielectric liners 216 (if present), and a second conductive pattern 1242 of the conductive patterns 124 may be formed in the second dielectric layer 1262 to be in physical and electrical contact with the upper electrode layer 214 of the memory device 210. It should be noted that the second conductive pattern 1242 illustrated in a pad form is an example, the second conductive pattern 1242 may be formed as a conductive via or a combination of a conductive via and pad using such as a dual damascene process. In some embodiments, the structure shown in FIG. 8 corresponds to the simplified structure in the dashed box A of FIG. 1.

FIG. 9 illustrates a schematic cross-sectional view of a variation of the structure shown in FIG. 8, in accordance with some embodiments. In some embodiments, the structure shown in FIG. 9 corresponds to the simplified structure in the dashed box A of FIG. 1. Unless specified otherwise, the materials and the formation methods of the components in these embodiments are essentially the same as the like components, which are denoted by like reference numerals in the embodiments shown in FIGS. 1 and 8.

Referring to FIG. 9 and with reference to FIG. 8, the structure shown in FIG. 9 is similar to the structure shown in FIG. 8, except that the data storage structure 312 of a memory device 210-1 further includes a third layer 212C vertically interposed between the lower electrode layer 211 and the first layer 212A. In some embodiments, the third layer 212C is made of a different material than the first layer 212A and the second layer 212B. For example, the material of the third layer 212C includes aluminum nitride (AlN), aluminum oxide (AlₓO_{y}), hafnium nitride (HfN), hafnium oxide (HfOₓ), the like, combinations thereof, suitable high-k dielectric material(s), or other suitable dielectric(s). In some embodiments, the first layer 212A is made of aluminum oxynitride (AlOₓN_{y}), and the third layer 212C is made of aluminum oxide (AlₓO_{y}), aluminum nitride (AlN), or a combination thereof. In some embodiments, the first layer 212A is made of hafnium oxynitride (HfOₓN_{y}), and the third layer 212C is made of hafnium oxide (HfOₓ), hafnium nitride (HfN), or a combination thereof. Depending on the product requirements, the first and third layers may have different materials than the aforementioned materials.

In some embodiments, the thickness 2122H of the first layer 212A is substantially equal to or greater than the thickness 2121H of the third layer 212C. For example, a ratio of the thickness 2122H to the thickness 2121H is in a range of about 1:1 and about 6:1. In some embodiments, the first layer 212A has been subjected to the plasma treatment after the deposition of the first material layer, while the third layer 212C may not be subjected to the plasma treatment. The first layer 212A may have a larger amount of oxygen vacancies than the third layer 212C. In some embodiments, the third layer 212C has the melting point higher than the melting point of the second layer 212B. In some embodiments, the thermal conductivity of the third layer 212C is greater than the thermal conductivity of the second layer 212B. By configuring the third layer 212C at the bottom of the data storage structure 312, the thermal stability and the thermal conductivity of the data storage structure 312 of the memory device 210-1 may be improved and/or enhanced.

Embodiments may have one or a combination of the following features and/or advantages. By placing the first layer having better thermal conductivity at the bottom of the data storage structure, the memory device may have the improved heat-dissipating ability, and heat accumulation at the interface of the lower electrode layer and the data storage structure may be reduced. The first layer of the data storage structure may have a higher melting point than the second layer to improve the thermal stability of the data storage structure. By configuring the data storage structure having improved thermal stability, the memory device may have a larger read window after cycling. By providing the greater amount of oxygen vacancies in the data storage structure, the forming voltage of the memory device may be reduced, as compared to the conventional data storage layer of the comparative example. Accordingly, the memory device in the semiconductor structure may have better electrical performance and improved reliability. The semiconductor structure having the memory device may be used in various applications (e.g., automotive electronics, computing, and communication applications, etc.).

Although the disclosed figures and description are described in relation to RRAM devices, it will be appreciated that the disclosed reactivity reducing layer is not limited to such memory devices. In alternative embodiments, the disclosed data storage structure may also be applied to other types of memory devices, such as, but not limited to conductive bridge random access memory (CBRAM), phase change random access memory (PCRAM), ferroelectric random access memory (FRAM), or the like.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

According to some embodiments, a semiconductor structure includes a memory device including a first electrode layer, a second electrode layer disposed over the first electrode layer, and a data storage structure interposed between the first electrode layer and the second electrode layer. The data storage structure includes a first layer and a second layer. A thermal conductivity of the first layer is greater than that of the second layer.

According to some embodiments, a semiconductor structure includes a memory device embedded in an interconnect structure over a substrate. The memory device includes a first electrode layer, a data storage structure overlying the first electrode layer and having a variable resistance, and a capping layer. The data storage structure includes a stack of a first dielectric material and a second dielectric material, where the first dielectric material has a melting point different from a melting point of the second dielectric material. The capping layer between the data storage structure and the first electrode layer or a top electrode layer overlying the data storage structure.

According to some embodiments, a method for forming a semiconductor structure includes forming a memory device in an interconnect structure over a substrate. The memory device includes a data storage structure formed over a first electrode layer and below a second electrode layer. The data storage structure includes a first layer formed over the first electrode layer and a second layer formed over the first layer and below the second electrode layer. A thermal conductivity of the first layer is different from a thermal conductivity of the second layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a memory device comprising:
a first electrode layer;
a second electrode layer disposed over the first electrode layer; and
a data storage structure interposed between the first electrode layer and the second electrode layer, the data storage structure comprising:
a first layer and
a second layer, wherein a thermal conductivity of the first layer is greater than a thermal conductivity of the second layer.

2. The semiconductor structure of claim 1, wherein a melting point of the first layer is higher than a melting point of the second layer.

3. The semiconductor structure of claim 1, wherein the first layer is close to the first electrode layer, the second layer connected to the first layer is close to the second electrode layer, and a relative density of the first layer is less than a relative density of the second layer.

4. The semiconductor structure of claim 1, wherein the first layer has a ratio of nitrogen to oxygen greater than 0.25.

5. The semiconductor structure of claim 1, wherein the memory device further comprises:
a capping layer interposed between the data storage structure and the second electrode layer.

6. The semiconductor structure of claim 5, wherein the memory device further comprises:
sidewall spacers disposed on the second layer of the data storage structure and extending along sidewalls of the capping layer and the second electrode layer.

7. The semiconductor structure of claim 1, wherein the data storage structure further comprises:
a third layer interposed between the first layer and the first electrode layer, wherein the third layer has a different material than the first layer and has a thermal conductivity greater than the thermal conductivity of the second layer.

8. The semiconductor structure of claim 7, wherein a thickness of the first layer is greater than a thickness of the third layer.

9. The semiconductor structure of claim 7, wherein the first layer is a metal oxynitride layer having a first metal, and the third layer comprises the first metal.

10. The semiconductor structure of claim 1, further comprising:
an interconnect structure disposed over a semiconductor substrate, wherein the memory device is embedded in the interconnect structure.

11. A semiconductor structure, comprising:
a memory device embedded in an interconnect structure over a substrate, the memory device comprising:
a first electrode layer;
a data storage structure overlying the first electrode layer and having a variable resistance, the data storage structure comprising:
a stack of a first dielectric material and a second dielectric material, wherein the first dielectric material has a melting point different from a melting point of the second dielectric material; and
a capping layer between the data storage structure and the first electrode layer or a top electrode layer overlying the data storage structure.

12. The semiconductor structure of claim 11, wherein the melting point of the first dielectric material is at least about 1.2 times greater than the melting point of the second dielectric material.

13. The semiconductor structure of claim 11, wherein a thermal conductivity of the first dielectric material is at least about 30 times greater than a thermal conductivity of the second dielectric material.

14. The semiconductor structure of claim 11, wherein the first dielectric material is a metal oxynitride layer.

15. The semiconductor structure of claim 11, wherein a ratio of nitrogen to oxygen of the first dielectric material is less than 3.

16. The semiconductor structure of claim 11, wherein the data storage structure further comprises:
a third dielectric material interposed between the first dielectric material and the first electrode layer, and a melting point of the third dielectric material is higher than the melting point of the second dielectric material.

17. A method for forming a semiconductor structure, comprising:
forming a memory device in an interconnect structure over a substrate, wherein the memory device comprises:
a data storage structure formed over a first electrode layer and below a second electrode layer, wherein the data storage structure comprises:
a first layer formed over the first electrode layer; and
a second layer formed over the first layer and below the second electrode layer, wherein a thermal conductivity of the first layer is different from a thermal conductivity of the second layer.

18. The method of claim 17, wherein forming the memory device comprises:
depositing a metal oxynitride layer over the first electrode layer; and
performing a plasma treatment on the metal oxynitride layer to form the first layer of the data storage structure.

19. The method of claim 17, wherein a melting point of the first layer is higher than that of the second layer.

20. The method of claim 17, wherein forming the memory device comprises:
forming a third layer on the first electrode layer;
forming the first layer and the second layer on the third layer, wherein the first layer is interposed between the third layer and the second layer, and a thermal conductivity of the third layer is greater than the thermal conductivity of the second layer.
